(19) United States
(12) Patent Application Publication
(10) Pub. No.: US 2014/0253218 A1
(43) Pub. Date: Sep. 11, 2014

(54) Multi-Gate Field Effect Transistor

(71) Applicant: Microchip Technology Incorporated, Chandler, AZ (US)

(72) Inventors: Gregory Dix, Tempe, AZ (US); Joe Depew, Port Crane, NY (US); Terry L. Cleveland, Endicott, NY (US)

(21) Appl. No.: 14/202,634

(22) Filed: Mar. 10, 2014

Related U.S. Application Data
(60) Provisional application No. 61/776,500, filed on Mar. 11, 2013.

(51) Int. Cl. H01L 29/78; H03K 17/10; H01L 29/66

(52) U.S. Cl. CPC H01L 29/7831; H01L 29/66484; H03K 17/102
USPC 327/434; 257/365; 438/283

(57) ABSTRACT

An improved field effect transistor (FET) is provided by segmenting the gates of a power FET wherein a controller can “decide” how much of the FET to use, thus increasing efficiency.

### CROSS REFERENCE TO RELATED APPLICATIONS

This application claims the benefit of U.S. Provisional Patent Application Ser. No. 61/776,500, filed Mar. 11, 2013, which is hereby incorporated by reference in its entirety for all purposes as if fully set forth herein.

### TECHNICAL FIELD

The present disclosure relates to field effect transistors, in particular to a multi-gate field effect transistor.

### BACKGROUND

Switched mode power supplies for converting electric power are nearly ubiquitous in today's world. Due to the fact that a switched mode power supply typically exhibits high efficiency, it is attractive for mobile or portable electronic devices, as these normally run off batteries. Nevertheless, switched mode power supplies do exhibit inefficiencies, depending on the load condition. In part, this results because the power transistors, typically field effect transistors, are generally fixed in operation do not allow for optimal control.

Accordingly, there exists a need to increasing efficiency of switched mode power supplies across a broad range of load conditions. To this end, improved field effect transistors are needed that allow customized control.

### SUMMARY

According to various embodiments, an improved field effect transistor (FET) can be provided by segmenting the gates of a power FET wherein a controller can “decide” how much of the FET to use, thus increasing efficiency across the whole range.

A power field effect transistor, in accordance with embodiments includes a semiconductor chip with a plurality of source and drain contacts each coupled in parallel, and a plurality of gate areas separated from each other, wherein each gate is connected to a separate bond pad. In some embodiments, the gate bond pads are configured to be controlled selectively to determine a functional property of the power FET. In some embodiments, the FET comprises two gates insulated from each other and common drain and source regions. In some embodiments, the FET includes a plurality of n gates, wherein n>2.

A power field effect transistor (FET) arranged within a package, in accordance with embodiments includes a semiconductor chip with plurality of source and drain contacts connected to respective pins of the package, and a plurality of gates separated from each other which are configured to be connected in parallel to determine a functional property of the power FET, wherein each gate is connected to a separate pin of the package.

A method, for manufacturing a semiconductor chip, in accordance with embodiments includes providing a plurality of source and drain contacts each coupled in parallel; and providing a plurality of gate areas separated from each other, wherein each gate is connected to a separate bond pad. In some embodiments, the gate bond pads are configured to be controlled selectively to determine a functional property of the power FET. In some embodiments, the FET comprises two gates insulated from each other and common drain and source regions. In some embodiments, the FET includes a plurality of n gates, wherein n>2.

A system in accordance with embodiments includes a power FET comprising two gates insulated from each other and common drain and source regions, and a controller configured to provide separate control signals for each of the two gates of the power FET. In some embodiments, the gate bond pads are configured to be controlled selectively to determine a functional property of the power FET. In some embodiments, the FET comprises two gates insulated from each other and common drain and source regions. In some embodiments, the FET includes a plurality of n gates, wherein n>2.

A method in accordance with embodiments includes providing a power FET comprising two gates insulated from each other and common drain and source regions, and providing a controller configured to provide separate control signals for each of the two gates of the power FET. In some embodiments, the gate bond pads are configured to be controlled selectively to determine a functional property of the power FET. In some embodiments, the FET comprises two gates insulated from each other and common drain and source regions. In some embodiments, the FET includes a plurality of n gates, wherein n>2.

These, and other, aspects of the disclosure will be better appreciated and understood when considered in conjunction with the following description and the accompanying drawings. It should be understood, however, that the following description, while indicating various embodiments of the disclosure and numerous specific details thereof, is given by way of illustration and not of limitation. Many substitutions, modifications, additions and/or rearrangements may be made within the scope of the disclosure without departing from the spirit thereof, and the disclosure includes all such substitutions, modifications, additions and/or rearrangements.

### BRIEF DESCRIPTION OF THE DRAWINGS

The drawings accompanying and forming part of this specification are included to depict certain aspects of the disclosure. It should be noted that the features illustrated in the drawings are not necessarily drawn to scale. A more complete understanding of the disclosure and the advantages thereof may be acquired by referring to the following description, taken in conjunction with the accompanying drawings in which like reference numbers indicate like features and wherein:

FIG. 1A is a diagram of a prior art power field effect transistor (FET).

FIG. 1B is a diagram illustrating pin/package configuration for a power FET.

FIG. 2 is an example of a driver circuit.

FIG. 3 is a graph of efficiency vs. load current for various power FETs.

FIG. 4 is a diagram illustrating a power FET in accordance with embodiments.

FIG. 5A illustrates an example of a FET die.

FIG. 5B illustrates an example of a lead frame for the FET die of FIG. 5A.

FIG. 6 illustrates an exemplary drive circuit using a power FET in accordance with embodiments.

FIG. 7 is a graph of efficiency vs. load current for power FETs in accordance with embodiments.

FIG. 8 is a diagram illustrating an exemplary transistor cell.

### DETAILED DESCRIPTION

The disclosure and various features and advantageous details thereof are explained more fully with reference to the exemplary, and therefore non-limiting, embodiments illustrated in the accompanying drawings and detailed in the following description. It should be understood, however, that the detailed description and the specific examples, while indicating the preferred embodiments, are given by way of illustration only and not by way of limitation. Descriptions of known programming techniques, computer software, hardware, operating platforms and protocols may be omitted so as not to unnecessarily obscure the disclosure in detail. Various substitutions, modifications, additions and/or rearrangements within the spirit and/or scope of the underlying inventive concept will become apparent to those skilled in the art from this disclosure.

According to various embodiments, a power FET device can be provided that allows pin out of more than two (2) gates. By segmenting the gate of a power FET into “n” segments the users, and/or controller can select how much of the FET to use. By dynamically selecting the size of the FET based on current load the overall efficiency across a whole range of operation can be optimized with no additional devices. Thus, while such a device has common source and drain regions that are coupled in parallel, the gates are separated and can be controlled to include associated drain and source regions. For example, according to some embodiments, common power MOSFETs comprise a plurality of transistor cells that are coupled in parallel by the internal metal layers. According to various embodiments, while drain and source regions of these cells are connected internally in parallel, only the gates of some cells are coupled in parallel to form a plurality of gates that are separated from each other. In summary, the present subject matter is not restricted to any particular FET technology but can be applied to any type of field effect transistor.

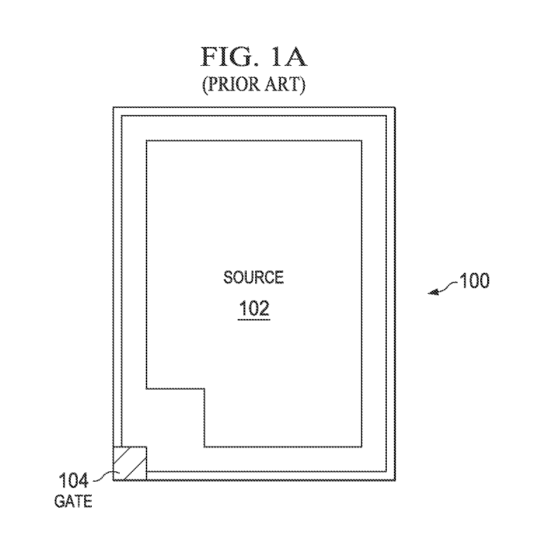

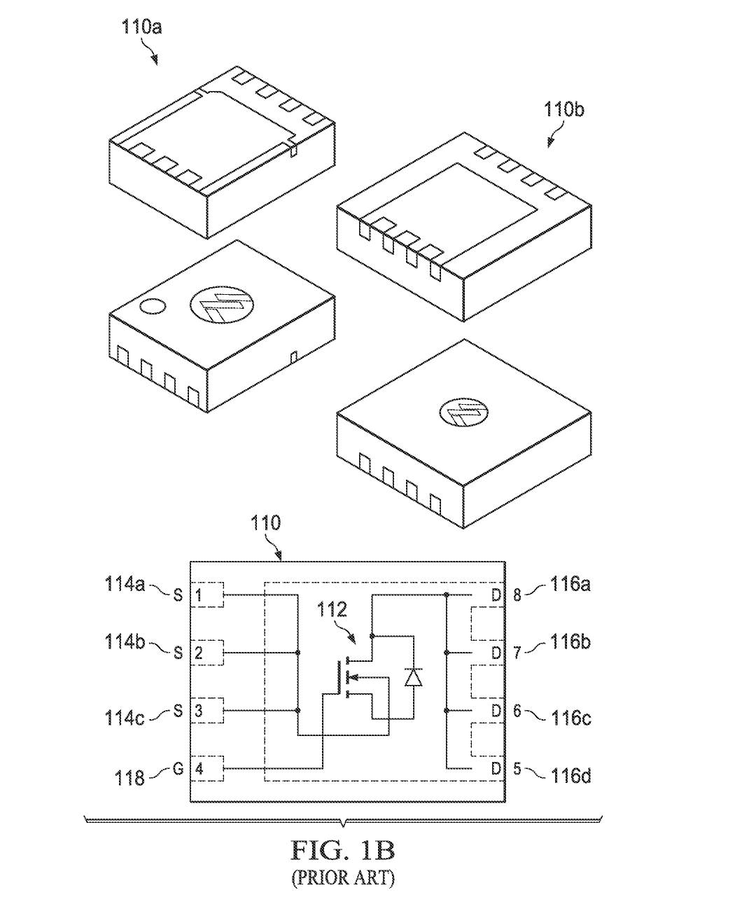

A common structure in switching regulators is two power FETs stacked on top of one another. In operation, such upper and lower FETs take turns being switched on. FIG. 1A shows a conventional power FET design 100 that can be used as an upper or lower power FET in a driver circuit. As can be seen, such a conventional transistor 100 includes a source 102 and has a single gate 104 and associated contact.

FIG. 1B shows a typical N-channel power MOSFET 112 and its internal connection(s). In particular, the integrated circuit package 110 may be embodied, for example, as shown at 110a and 110b. The MOSFET 112 includes source connections 114a-114b, drain connections 116a-116d, and s single gate connection 118. As can be appreciated, the multiple drain and source connections provide for a low resistance connection.

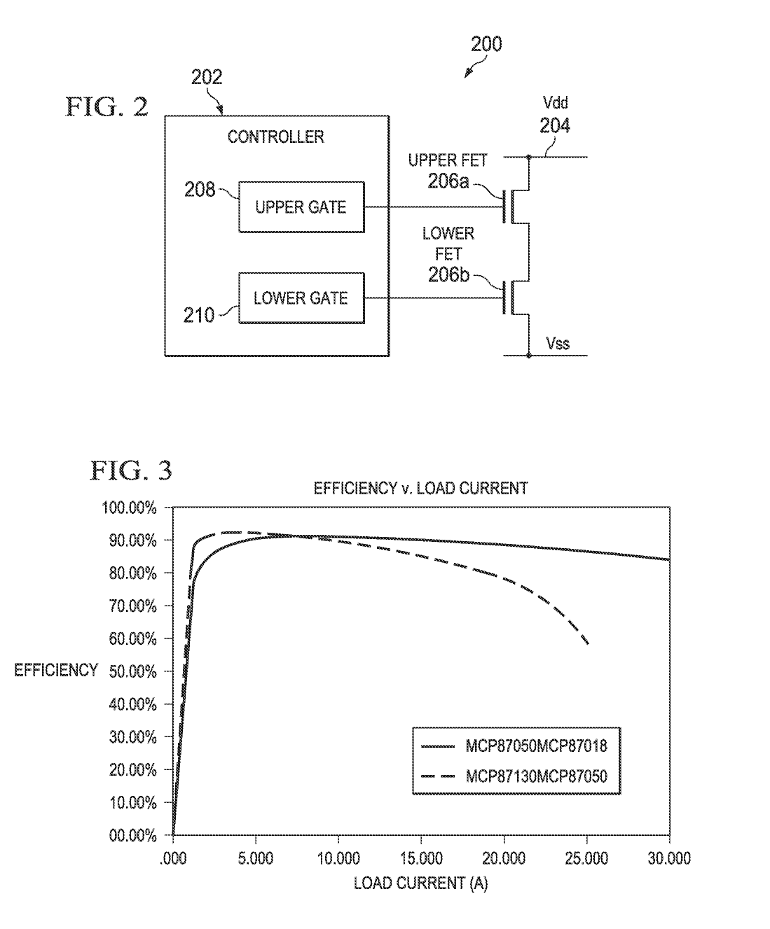

FIG. 2 illustrates a drive circuit 200 including a controller 202 and transistor 204, including upper FET 206a and lower FET 206b. The controller 202 drives the gates of the upper and lower transistors 206a, 206b over connections 208, 210, respectively. Upper and lower FET sizes are chosen to provide a good efficiency based on load conditions of, for example, a switched mode power application.

As shown in the diagram of FIG. 3, at large loads, a design would include large FET devices. For example, high speed N-channel power MOSFET MCP87050 and MCP87018 manufactured by Assignee could be chosen. However, at light load, a better choice would be the N-channel power MOSFET MCP87130 and MCP87050, also manufactured by Assignee. The power FET can be an NMOS or PMOS device. According to further embodiments, such power MOSFETs may be integrated into mixed signal device such as a microcontroller.

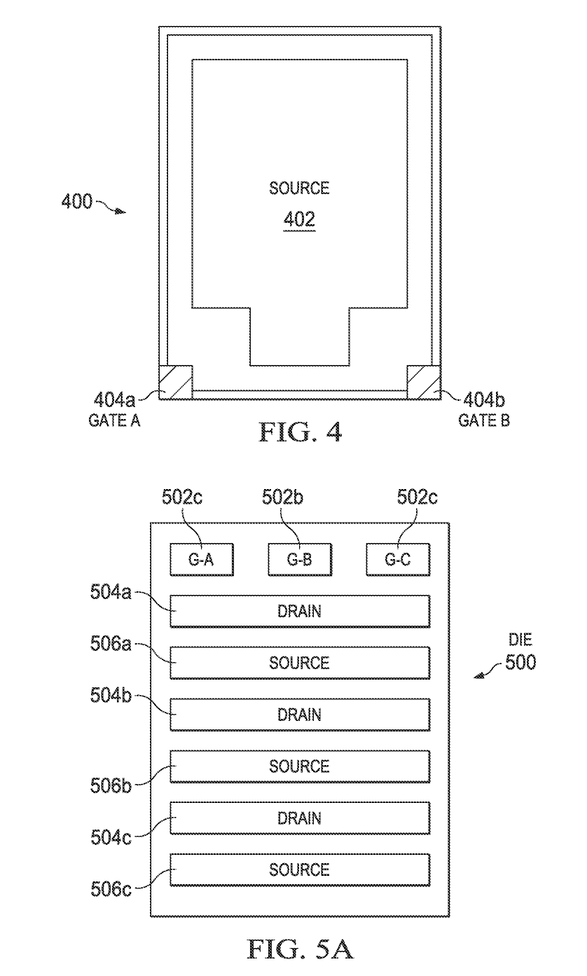

Turning now to FIG. 4, a power FET 400 according to embodiments is shown. In the example illustrated, the power FET 400 includes source 402 and a first gate 404a and a second gate 404b. Such a device can be divided into two parts with Gate A 404a operating a portion of the total FET, and Gate B 404b the remainder. Thus, according to various embodiments, a common drain and source regions are provided, but the gate is split into multiple parts (two or more) wherein the gates are connected to individual gate pins that are internally not shorted. Thus, each gate 404a, 404b can be controlled separately. The gates 404a, 404b can externally be shorted to provide for the full power of the device. However its parameters can be scaled down by only using one of the two gates. If more than two gates are implemented, an even greater scalability can be achieved.

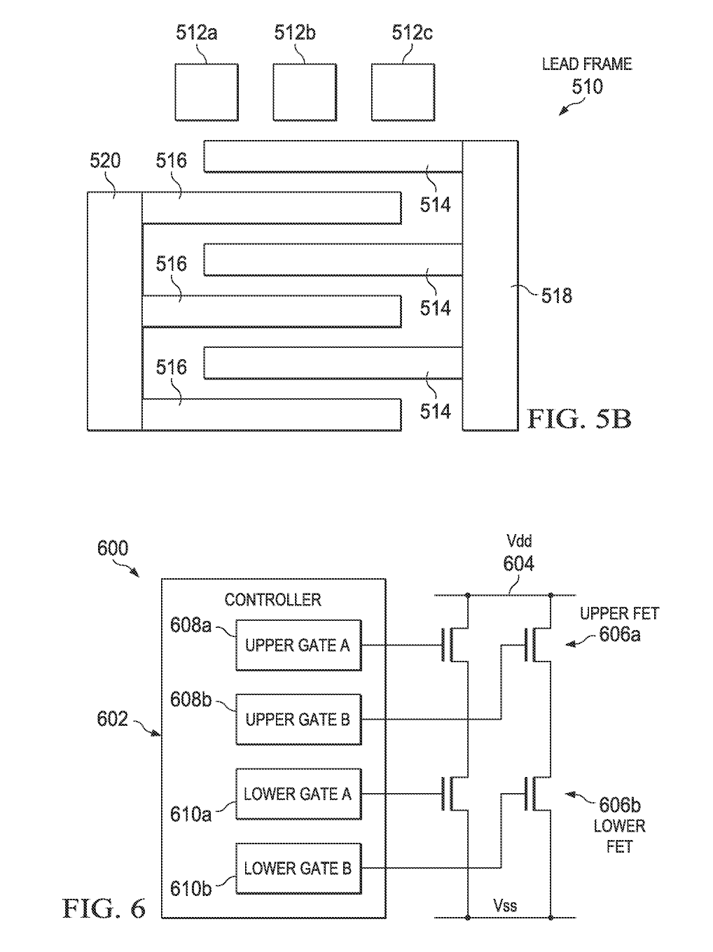

Multiple gates can be implemented as shown in FIG. 5A and FIG. 5B. In particular, shown is an implementation using a flip-chip on lead frame technique. More particularly, an example die is shown at 500. The die 500 includes gate contact elements 502a-502c, drain contact elements 504a-504c, and source contact elements 506a-506c.

Shown in FIG. 5B is a corresponding lead frame 510. The lead frame 510 includes gates leads 512a-512c. The lead frame 510 further includes drain lead fingers 514 and source lead fingers 516. The drain lead fingers 514 are arranged with a contact strip 518 to form a single contact element. Likewise, the source lead fingers 516 are arranged with a contact strip 520 forming a single contact element.

The power transistor in accordance with embodiments may be formed, for example, by providing solder “ball bumps” for the contact elements 502a-502c, 504a-504c, and 506a-506c, and attaching the lead frame 510 to the die 500 by appropriate heating. A suitable flip-chip on lead frame technique for manufacturing such a device is generally known from commonly-assigned US Patent Application US-2012-0126406-A1, which is hereby incorporated by reference.

FIG. 6 illustrates a drive circuit 600 including transistors in accordance with embodiments. The drive circuit 600 includes a controller 602 and transistors 604, including upper FET 606a and lower FET 606b. The upper and lower FET sizes can have the same maximum load size as in the drive circuit of FIG. 2, but they have two gate connections to segment how much of the device is used. That is, as shown, the upper FET 606a via connection 608a, 608b and the lower FET 606b via connections 610a, 610b.

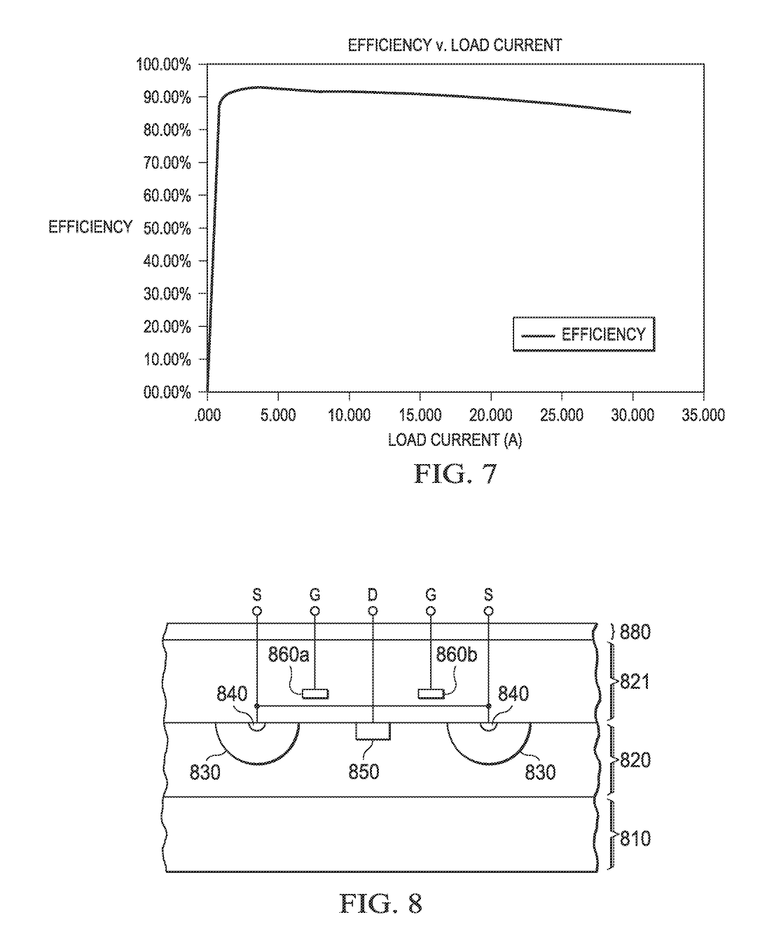

FIG. 7 shows a resulting graph similar to the graph shown in FIG. 3. With a selectable number of gates, the virtual size of the FETs can be controlled based on current load and an optimal efficiency can be obtained. That is, efficiency can be relatively stable over a range of load conditions.

It is noted that the design of a power FET according to various embodiments, is not limited to two gates. Rather, a plurality of n gates may be provided. This may be only limited by the actual area available on the silicon die.

In summary, a single FET selection for a wide range of current load can be provided by a flexible assignment of gates according to various embodiments. Thus, benefits of a “multi phase” solution for a single phase cost are provided.

Finally, FIG. 8 shows a cross section through a possible embodiment of a power transistor in accordance with embodiments. As can be seen a standard field effect power transistor may be formed by a plurality of cells coupled in parallel. A cell can be formed symmetrically as shown. Here, on a substrate 810, an epitaxial layer 820 may be formed. Within the epitaxial layer 820, a cell may be formed by base regions 830 in which source regions 840 are embedded. In-between the two base regions, a drain region 850 may be formed. For each cell, a plurality of gates 860 may be formed within an insulation layer 821 on top of the epitaxial layer 820, wherein the gates 860 at least cover a lateral channel region within the base region between the source region 840 and the epitaxial layer 820. Other cells are arranged next to this cell. Also, other cell structures can be used, for example, the base and source region can be symmetrical so that a base region can also be used for a neighboring cell. An additional insulating layer 821 may be provided on top of the structure.

Although the invention has been described with respect to specific embodiments thereof, these embodiments are merely illustrative, and not restrictive of the invention. The description herein of illustrated embodiments of the invention, including the description in the Abstract and Summary, is not intended to be exhaustive or to limit the invention to the precise forms disclosed herein (and in particular, the inclusion of any particular embodiment, feature or function within the Abstract or Summary is not intended to limit the scope of the invention to such embodiment, feature or function). Rather, the description is intended to describe illustrative embodiments, features and functions in order to provide a person of ordinary skill in the art context to understand the invention without limiting the invention to any particularly described embodiment, feature or function, including any such embodiment feature or function described in the Abstract or Summary.

While specific embodiments of, and examples for, the invention are described herein for illustrative purposes only, various equivalent modifications are possible within the spirit and scope of the invention, as those skilled in the relevant art will recognize and appreciate. As indicated, these modifications may be made to the invention in light of the foregoing description of illustrated embodiments of the invention and are to be included within the spirit and scope of the invention. Thus, while the invention has been described herein with reference to particular embodiments thereof, a latitude of modification, various changes and substitutions are intended in the foregoing disclosures, and it will be appreciated that in some instances some features of embodiments of the invention will be employed without a corresponding use of other features without departing from the scope and spirit of the invention as set forth. Therefore, many modifications may be made to adapt a particular situation or material to the essential scope and spirit of the invention.

Reference throughout this specification to “one embodiment”, “an embodiment”, or “a specific embodiment” or similar terminology means that a particular feature, structure, or characteristic described in connection with the embodiment is included in at least one embodiment and may not necessarily be present in all embodiments. Thus, respective appearances of the phrases “in one embodiment”, “in an embodiment”, or “in a specific embodiment” or similar terminology in various places throughout this specification are not necessarily referring to the same embodiment. Furthermore, the particular features, structures, or characteristics of any particular embodiment may be combined in any suitable manner with one or more other embodiments. It is to be understood that other variations and modifications of the embodiments described and illustrated herein are possible in light of the teachings herein and are to be considered as part of the spirit and scope of the invention.

In the description herein, numerous specific details are provided, such as examples of components and/or methods, to provide a thorough understanding of embodiments of the invention. One skilled in the relevant art will recognize, however, that an embodiment may be able to be practiced without one or more of the specific details, or with other apparatus, systems, assemblies, methods, components, materials, parts, and/or the like. In other instances, well-known structures, components, systems, materials, or operations are not specifically shown or described in detail to avoid obscuring aspects of embodiments of the invention. While the invention may be illustrated by using a particular embodiment, this is not and does not limit the invention to any particular embodiment and a person of ordinary skill in the art will recognize that additional embodiments are readily understandable and are a part of this invention.

As used herein, the terms “comprises,” “comprising,” “includes,” “including,” “has,” “having,” or any other variation thereof, are intended to cover a non-exclusive inclusion. For example, a process, product, article, or apparatus that comprises a list of elements is not necessarily limited only those elements but may include other elements not expressly listed or inherent to such process, process, article, or apparatus.

Furthermore, the term “or” as used herein is generally intended to mean “and/or” unless otherwise indicated. For example, a condition A or B is satisfied by any one of the following: A is true (or present) and B is false (or not present), A is false (or not present) and B is true (or present), and both A and B are true (or present). As used herein, including the claims that follow, a term preceded by “a” or “an” (and “the” when antecedent basis is “a” or “an”) includes both singular and plural of such term, unless clearly indicated within the claim otherwise (i.e., that the reference “a” or “an” clearly indicates only the singular or only the plural). Also, as used in the description herein and throughout the claims that follow, the meaning of “in” includes “in” and “on” unless the context clearly dictates otherwise.

It will be appreciated that one or more of the elements depicted in the drawings/figures can also be implemented in a more separated or integrated manner, or even removed or rendered as inoperable in certain cases, as is useful in accordance with a particular application. Additionally, any signal arrows in the drawings/Figures should be considered only as exemplary, and not limiting, unless otherwise specifically noted.

What is claimed is:

1. A power field effect transistor, comprising:
a semiconductor chip with a plurality of source and drain contacts each coupled in parallel, and a plurality of gate areas separated from each other, wherein each gate is connected to a separate bond pad.

2. The power FET according to claim 1, wherein the gate bond pads are configured to be controlled selectively to determine a functional property of the power FET.

3. The power FET according to claim 2, wherein the FET comprises two gates insulated from each other and common drain and source regions.

4. The power FET according to claim 1, comprising a plurality of n gates, wherein n>2.

5. A power field effect transistor (FET) arranged within a package, comprising a semiconductor chip with plurality of source and drain contacts connected to respective pins of the package, and a plurality of gates separated from each other which are configured to be connected in parallel to determine a functional property of the power FET, wherein each gate is connected to a separate pin of the package.

6. A method, for manufacturing a semiconductor chip, comprising:
providing a plurality of source and drain contacts each coupled in parallel; and
providing a plurality of gate areas separated from each other, wherein each gate is connected to a separate bond pad.

7. The method according to claim 6, wherein the gate bond pads are configured to be controlled selectively to determine a functional property of the power FET.

8. The method according to claim 7, wherein the FET comprises two gates insulated from each other and common drain and source regions.

9. The power FET according to claim 6, comprising a plurality of n gates, wherein n>2.

10. A system comprising:
a power FET comprising two gates insulated from each other and common drain and source regions, and
a controller configured to provide separate control signals for each of the two gates of the power FET.

11. The system according to claim 10, wherein the gate bond pads are configured to be controlled selectively to determine a functional property of the power FET.

12. The system according to claim 11, wherein the FET comprises two gates insulated from each other and common drain and source regions.

13. The system according to claim 10, comprising a plurality of n gates, wherein n>2.

14. A method comprising:
providing a power FET comprising two gates insulated from each other and common drain and source regions, and
providing a controller configured to provide separate control signals for each of the two gates of the power FET.

15. The method according to claim 14, wherein the gate bond pads are configured to be controlled selectively to determine a functional property of the power FET.

16. The method according to claim 15, wherein the FET comprises two gates insulated from each other and common drain and source regions.

17. The method according to claim 16, comprising a plurality of n gates, wherein n>2.
